(19) United States
(12) Patent Application Publication
(10) Pub. No.: US 2026/0332963 A1
(43) Pub. Date: Oct. 22, 2026

(54) SYSTEM AND METHOD FOR COMMUNICATION VIA ULTRASONIC PRESSURE WAVES IN A SERVER COOLANT FLUID

(71) Applicant: Dell Products L.P., Round Rock, TX (US)

(72) Inventors: Sandor Farkas, Round Rock, TX (US); Timothy M. Lambert, Austin, TX (US); Michael J. Stumpf, Cedar Park, TX (US)

(73) Assignee: Dell Products L.P., Round Rock, TX (US)

(21) Appl. No.: 19/181,563

(22) Filed: Apr. 17, 2025

(51) Int. Cl. H04R 17/10; H04R 1/28; H05K 7/20

(52) U.S. Cl. CPC H04R 17/10; H04R 1/2803; H05K 7/20272; H05K 7/2079

(57) ABSTRACT

Embodiments of the present disclosure provide a system and method for communication via ultrasonic pressure waves in a server coolant fluid. According to one embodiment, an ultrasonic communication system includes multiple servers configured in a computing cluster wherein each server in fluid communication with a Cooling Distribution Unit (CDU) via an input line and a return line. The ultrasonic communication system also includes multiple first ultrasonic transducers configured in either of the input line or the return line proximate the servers, and a second ultrasonic transducer configured in either of the input line or the return line proximate the CDU, wherein the CDU is configured to communicate with the servers using the second ultrasonic transducer and the first ultrasonic transducers.

### BACKGROUND

As the value and use of information continues to increase, individuals and businesses seek additional ways to process and store information. One option is an information handling system (IHS). An IHS generally processes, compiles, stores, and/or communicates information or data for business, personal, or other purposes. Because technology and information handling needs and requirements may vary between different applications, IHSs may also vary regarding what information is handled, how the information is handled, how much information is processed, stored, or communicated, and how quickly and efficiently the information may be processed, stored, or communicated. The variations in IHSs allow for IHSs to be general or configured for a specific user or specific use such as financial transaction processing, airline reservations, enterprise data storage, global communications, etc. In addition, IHSs may include a variety of hardware and software components that may be configured to process, store, and communicate information and may include one or more computer systems, data storage systems, and networking systems.

Groups of IHSs may be housed within data center environments. A data center may include a large number of IHSs, such as enterprise blade servers that are stacked and installed within computing racks, which may also be referred to as racks. A data center may include large numbers of such computing racks that are organized into rows of racks. Administration of such large groups of IHSs may require teams of remote and local administrators working in shifts in order to support around-the-clock availability of the data center operations while minimizing any downtime.

Racks provide a means for densely housing relatively large numbers of individual computing devices. A principal challenge with such dense packaging often involves providing sufficient cooling for each of the computing devices. As such, many newer computing rack designs have implemented liquid cooling systems, such as liquid immersion cooling, or liquid cooling provided by cold plates that are thermally coupled to the principal heat generating components of the computing device.

### SUMMARY

Embodiments of the present disclosure provide a system and method for communication via ultrasonic pressure waves in a server coolant fluid. According to one embodiment, an ultrasonic communication system includes multiple servers configured in a computing cluster wherein each server in fluid communication with a Cooling Distribution Unit (CDU) via an input line and a return line. The ultrasonic communication system also includes multiple first ultrasonic transducers configured in either of the input line or the return line proximate the servers, and a second ultrasonic transducer configured in either of the input line or the return line proximate the CDU, wherein the CDU is configured to communicate with the servers using the second ultrasonic transducer and the first ultrasonic transducers.

According to another embodiment, an Information Handling System (IHS) includes multiple servers configured in a computing cluster, each server in fluid communication with a Cooling Distribution Unit (CDU) via an input line and a return line, multiple first ultrasonic transducers configured in at least one a first of the input line or the return line proximate the servers or the CDU, and a second ultrasonic transducer configured in at least one of a second of the input line or the return line proximate a second server or the CDU, wherein the first server or CDU is configured to communicate with the second of the servers or the CDU using the second ultrasonic transducer and the first ultrasonic transducer.

### BRIEF DESCRIPTION OF THE DRAWINGS

The present invention(s) is/are illustrated by way of example and is/are not limited by the accompanying figures, in which like references indicate similar elements. Elements in the figures are illustrated for simplicity and clarity, and have not necessarily been drawn to scale.

FIGS. 1A and 1B are block diagrams illustrating certain components of a chassis comprising one or more compute sleds and one or more storage sleds that may be configured to implement the systems and methods described according to one embodiment of the present disclosure.

FIG. 2 illustrates an example of an IHS configured to implement systems and methods described herein according to one embodiment of the present disclosure.

FIG. 3 illustrates an example ultrasonic communication system that may be used to provide communication from a CDU to the servers of a data center according to one embodiment of the present disclosure.

FIG. 4 illustrates an exploded view showing several components of the example transducers that may be used for converting ultrasonic pressure waves in the lines to electrical signals and/or converting electrical signals to ultrasonic pressure waves according to one embodiment of the present disclosure.

FIG. 5 illustrates an example block diagram showing how the ultrasonic transducer may be used to convert ultrasonic signals to and from electrical signals according to one embodiment of the present disclosure.

FIGS. 6A and 6B illustrate several embodiments of example transducer assembly configurations that may be used by the ultrasonic communication system according to one embodiment of the present disclosure.

FIG. 7 illustrates an example graph showing how the ultrasonic communication system may perform according to one embodiment of the present disclosure.

FIG. 8 illustrates a graph showing an example pseudo-random binary sequence (PRBS) that may be used to enhance noise immunity of the ultrasonic communication system according to one embodiment of the present disclosure.

FIG. 9 illustrates an example graph showing how a signal may be recovered in the presence of noise according to one embodiment of the present disclosure.

### DETAILED DESCRIPTION

The present disclosure is described with reference to the attached figures. The figures are not drawn to scale, and they are provided merely to illustrate the disclosure. Several aspects of the disclosure are described below with reference to example applications for illustration. It should be understood that numerous specific details, relationships, and methods are set forth to provide an understanding of the disclosure. The present disclosure is not limited by the illustrated ordering of acts or events, as some acts may occur in different orders and/or concurrently with other acts or events. Furthermore, not all illustrated acts or events are required to implement a methodology in accordance with the present disclosure.

As described previously, liquid cooling for computing racks has become an attractive alternative to air cooling due in large part to the relatively dense housing of their constituent components, which can each generate relatively large levels of heat. Liquid cooling is being adopted in many data centers due to significant reduction in operational expenditures compared to air cooled systems. Liquid cooling systems usually utilize a cold plate that replaces the CPU's heat sink in which the cold plate is cooled using flexible conduits that circulate a liquid, such as a water, or a blend of water and other water-based materials. With increasing demand for higher performance and density, next generation architectures will require direct liquid cooling (DLC).

Vendors are increasingly creating platforms from off-the-shelf building blocks where designers at times, may not have the ability to influence or add to the design. Rather, they are often challenged to work with what they have and add additional value around these pre-built components. Many of these platforms use DLC for efficiency, cooling capacity, or both. DLC can be a drop-in replacement for server cooling, but it adds certain failure modes and challenges. For example, some data centers may be configured with IHSs provided from multiple vendors and types of equipment. Additionally, there is often no simple way for vendors to interface with many vendors' DLC equipment and still provide a layer of protection. It is difficult in practice to add chassis-external connections to a Baseboard Management Controller (BMC) that supports management actions. Due to this, server nodes now depend on an external system to cool them, yet have no idea of that subsystem's health.

Current solutions to these problems often require significant setup, such as awareness of local networks, which may be segmented or blocked, awareness of specific CDU vendor's API implementation and interface, special configuration requirements (e.g., specific to their connected CDU), and/or a separate monitoring computer. Most often, rather than doing all this complex configuration, customers often opt to use no protection at all. As will be described in detail herein below, embodiments of the present disclosure provide a system and method for communication via ultrasonic pressure waves in a server coolant fluid that enables reliable communication for CDUs and the servers so that cooling information may be reliably conveyed.

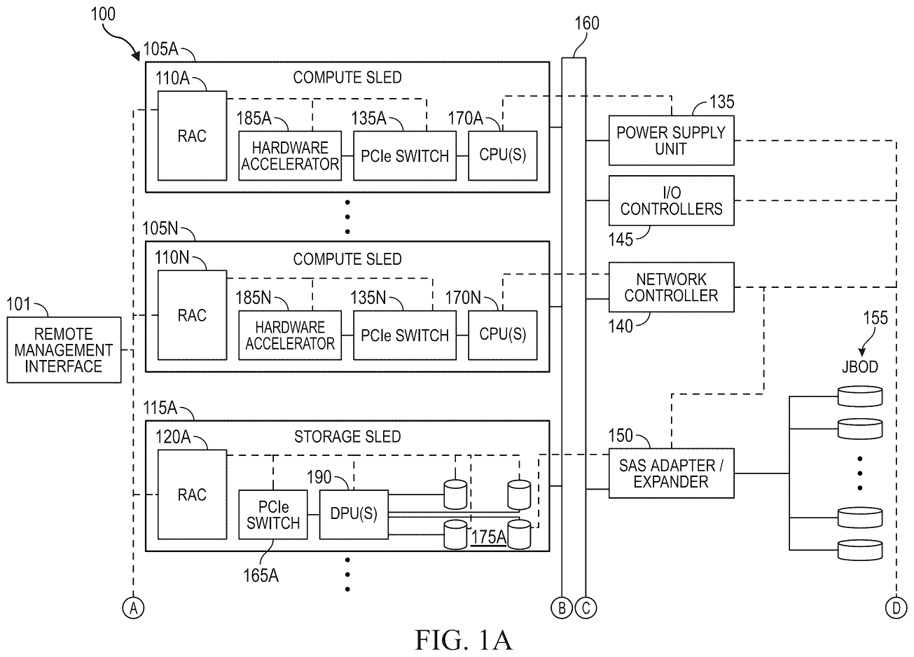

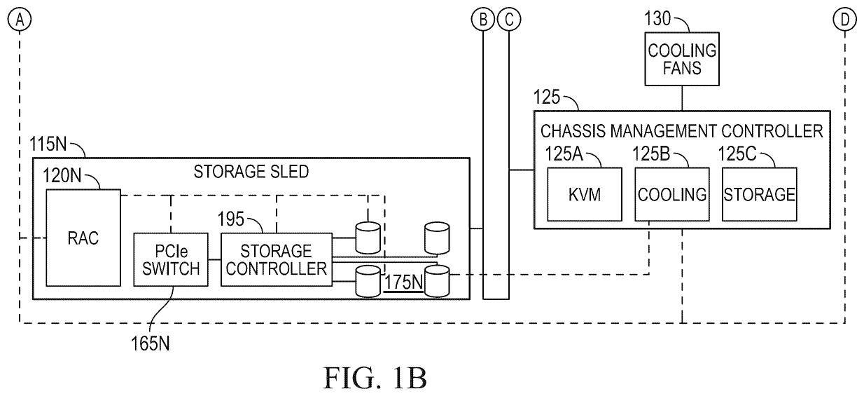

FIGS. 1A and 1B are block diagrams illustrating certain components of a chassis 100 comprising one or more compute sleds 105a-n and one or more storage sleds 115a-n that may be configured to implement the systems and methods described according to one embodiment of the present disclosure. Embodiments of chassis 100 may include a wide variety of hardware configurations in which one or more sleds 105a-n, 115a-n are installed in chassis 100. Such variations in hardware configuration may result from chassis 100 being factory assembled to include components specified by a customer that has contracted for manufacture and delivery of chassis 100. Upon delivery and deployment of a chassis 100, the chassis 100 may be modified by replacing and/or adding various hardware components, in addition to replacement of the removable sleds 105a-n, 115a-n that are installed in the chassis. In addition, once the chassis 100 has been deployed, firmware used by individual hardware components of the sleds 105a-n, 115a-n, or by other hardware components of chassis 100, may be modified in order to update the operations that are supported by these hardware components.

Chassis 100 may include one or more bays that each receive an individual sled (that may be additionally or alternatively referred to as a tray, blade, and/or node), such as compute sleds 105a-n and storage sleds 115a-n. Chassis 100 may support a variety of different numbers (e.g., 4, 8, 16, 32), sizes (e.g., single-width, double-width) and physical configurations of bays. Embodiments may include additional types of sleds that provide various storage, power and/or processing capabilities. For instance, sleds installable in chassis 100 may be dedicated to providing power management or networking functions. Sleds may be individually installed and removed from the chassis 100, thus allowing the computing and storage capabilities of a chassis to be reconfigured by swapping the sleds with diverse types of sleds, in some cases at runtime without disrupting the ongoing operations of the other sleds installed in the chassis 100.

Multiple chassis 100 may be housed within a rack. Data centers may utilize large numbers of racks, with various different types of chassis installed in various configurations of racks. The modular architecture provided by the sleds, chassis and racks allow for certain resources, such as cooling, power, and network bandwidth, to be shared by the compute sleds 105a-n and storage sleds 115a-n, thus providing efficiency improvements and supporting greater computational loads. For instance, certain computational tasks, such as computations used in machine learning and other artificial intelligence systems, may utilize computational and/or storage resources that are shared within an IHS, within an individual chassis 100 and/or within a set of IHSs that may be spread across multiple chassis of a data center.

Implementing computing systems that span multiple processing components of chassis 100 is aided by high-speed data links between these processing components, such as PCIe connections that form one or more distinct PCIe switch fabrics that are implemented by PCIe switches 135a-n, 165a-n installed in the sleds 105a-n, 115a-n of the chassis. These high-speed data links may be used to support algorithm implementations that span multiple processing, networking, and storage components of an IHS and/or chassis 100. For instance, computational tasks may be delegated to a specific processing component of an IHS, such as to a hardware accelerator 185a-n that may include one or more programmable processors that operate separate from the main CPUs 170a-n of computing sleds 105a-n. In various embodiments, such hardware accelerators 185a-n may include DPUs (Data Processing Units), GPUs (Graphics Processing Units), SmartNICs (Smart Network Interface Card) and/or FPGAs (Field Programmable Gate Arrays). These hardware accelerators 185a-n operate according to firmware instructions that may be occasionally updated, such as to adapt the capabilities of the respective hardware accelerators 185a-n to specific computing tasks.

Chassis 100 may be installed within a rack structure that provides at least a portion of the cooling utilized by the sleds 105a-n, 115a-n installed in chassis 100. In supporting airflow cooling, a rack may include one or more banks of cooling fans 130 that may be operated to ventilate heated air from within the chassis 100 that is housed within the rack. The chassis 100 may alternatively or additionally include one or more cooling fans 130 that may be similarly operated to ventilate heated air away from sleds 105a-n, 115a-n installed within the chassis. In this manner, a rack and a chassis 100 installed within the rack may utilize various configurations and combinations of cooling fans 130 to cool the sleds 105a-n, 115a-n and other components housed within chassis 100.

The sleds 105a-n, 115a-n may be individually coupled to chassis 100 via connectors that correspond to the bays provided by the chassis 100 and that physically and electrically couple an individual sled to a backplane 160. Chassis backplane 160 may be a printed circuit board that includes electrical traces and connectors that are configured to route signals between the various components of chassis 100 that are connected to the backplane 160 and between different components mounted on the printed circuit board of the backplane 160. In the illustrated embodiment, the connectors for use in coupling sleds 105a-n, 115a-n to backplane 160 include PCIe couplings that support high-speed data links with the sleds 105a-n, 115a-n. In various embodiments, backplane 160 may support diverse types of connections, such as cables, wires, midplanes, connectors, expansion slots, and multiplexers. In certain embodiments, backplane 160 may be a motherboard that includes various electronic components installed thereon. Such components installed on a motherboard backplane 160 may include components that implement all or part of the functions described with regard to the SAS (Serial Attached SCSI) expander 150, I/O controllers 145, network controller 140, chassis management controller 125 and power supply unit 135.

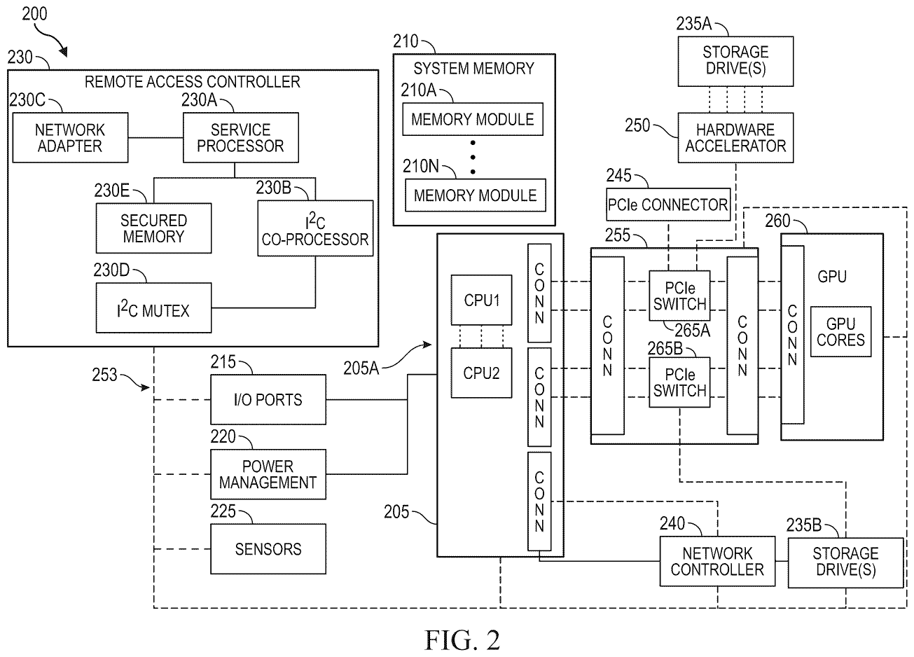

In certain embodiments, each individual sled 105a-n, 115a-n may be an IHS such as described with regard to IHS 200 of FIG. 2. Sleds 105a-n, 115a-n may individually or collectively provide computational processing resources that may be used to support a variety of e-commerce, multimedia, business, and scientific computing applications, such as artificial intelligence systems provided via cloud computing implementations. Sleds 105a-n, 115a-n are typically configured with hardware and software that provide leading-edge computational capabilities. Accordingly, services that are provided using such computing capabilities are typically provided as high-availability systems that operate with minimum downtime.

In high-availability computing systems, such as may be implemented using embodiments of chassis 100, any downtime that can be avoided is preferred. As described above, firmware updates are expected in the administration and operation of data centers, but it is preferable to avoid any downtime in making such firmware updates. For instance, in updating the firmware of the individual hardware components of the chassis 100, it is preferable that such updates can be made without having to reboot the chassis. As described in additional detail below, it is also preferable that updates to the firmware of individual hardware components of sleds 105a-n, 115a-n be likewise made without having to reboot the respective sled of the hardware component that is being updated.

As illustrated, each sled 105a-n, 115a-n includes a respective remote access controller (RAC) 110a-n, 120a-n. As described in additional detail with regard to FIG. 2, remote access controller 110a-n, 120a-n provides capabilities for remote monitoring and management of a respective sled 105a-n, 115a-n and/or of chassis 100. In support of these monitoring and management functions, remote access controllers 110a-n may utilize both in-band and sideband (i.e., out-of-band) communications with various managed components of a respective sled 105a-n and chassis 100. Remote access controllers 110a-n, 120a-n may collect diverse types of sensor data, such as collecting temperature sensor readings that are used in support of airflow cooling of the chassis 100 and the sled 105a-n, 115a-n. In addition, each remote access controller 110a-n, 120a-n may implement various monitoring and administrative functions related to a respective sled 105a-n, 115a-n, where these functions may be implemented using sideband bus connections with various internal components of the chassis 100 and of the respective sleds 105a-n, 115a-n. As described in additional detail below, in various embodiments, these capabilities of the remote access controllers 110a-n, 120a-n may be utilized in updating the firmware of hardware components of chassis 100 and/or of hardware components of the sleds 105a-n, 115a-n, without having to reboot the chassis or any of the sleds 105a-n, 115a-n.

The remote access controllers 110a-n, 120a-n that are present in chassis 100 may support secure connections with a remote management interface 101. In some embodiments, remote management interface 101 provides a remote administrator with various capabilities for remotely administering the operation of an IHS, including initiating updates to the firmware used by hardware components installed in the chassis 100. For example, remote management interface 101 may provide capabilities by which an administrator can initiate updates to all of the storage drives 175a-n installed in a chassis 100, or to all of the storage drives 175a-n of a particular model or manufacturer. In some instances, remote management interface 101 may include an inventory of the hardware, software, and firmware of chassis 100 that is being remotely managed through the operation of the remote access controllers 110a-n, 120a-n. The remote management interface 101 may also include various monitoring interfaces for evaluating telemetry data collected by the remote access controllers 110a-n, 120a-n. In some embodiments, remote management interface 101 may communicate with remote access controllers 110a-n, 120a-n via a protocol such the Redfish remote management interface.

In the illustrated embodiment, chassis 100 includes one or more compute sleds 105a-n that are coupled to the backplane 160 and installed within one or more bays or slots of chassis 100. Each of the individual compute sleds 105a-n may be an IHS, such as described with regard to FIG. 2. Each of the individual compute sleds 105a-n may include various different numbers and types of processors that may be adapted to performing specific computing tasks. In the illustrated embodiment, each of the compute sleds 105a-n includes a PCIe switch 135a-n that provides access to a hardware accelerator 185a-n, such as the described DPUs, GPUs, Smart NICs and FPGAs, which may be programmed and adapted for specific computing tasks, such as to support machine learning or other artificial intelligence systems. As described in additional detail below, compute sleds 105a-n may include a variety of hardware components, such as hardware accelerator 185a-n and PCIe switches 135a-n, that operate using firmware that may be occasionally updated.

As illustrated, chassis 100 includes one or more storage sleds 115a-n that are coupled to the backplane 160 and installed within one or more bays of chassis 100 in a similar manner to compute sleds 105a-n. Each of the individual storage sleds 115a-n may include various different numbers and types of storage devices. As described in additional detail with regard to FIG. 2, a storage sled 115a-n may be an IHS 200 that includes multiple solid-state drives (SSDs) 175a-n, where the individual storage drives 175a-n may be accessed through a PCIe switch 165a-n of the respective storage sled 115a-n.

As illustrated, a storage sled 115a may include one or more DPUs (Data Processing Units) 190 that provide access to and manage the operations of the storage drives 175a of the storage sled 115a. Use of a DPU 190 in this manner provides low-latency and high-bandwidth access to numerous SSDs 175a. These SSDs 175a may be utilized in parallel through NVMe transmissions that are supported by the PCIe switch 165a that connects the SSDs 175a to the DPU 190. In some instances, PCIe switch 165a may be an integrated component of a DPU 190. The immense data storage and retrieval capabilities provided by such storage sled 115a implementations may be harnessed by offloading storage operations directed as storage drives 175a to a DPU 190a, and thus without relying on the main CPU of the storage sled, or of any other component of chassis 100. As indicated in FIG. 1, chassis 100 may also include one or more storage sleds 115n that provide access to storage drives 175n via a storage controller 195. In some embodiments, storage controller 195 may provide support for RAID (Redundant Array of Independent Disks) configurations of logical and physical storage drives, such as storage drives provided by storage sled 115n. In some embodiments, storage controller 195 may be a HBA (Host Bus Adapter) that provides more limited capabilities in accessing storage drives 175n.

In addition to the data storage capabilities provided by storage sleds 115a-n, chassis 100 may provide access to other storage resources that may be installed components of chassis 100 and/or may be installed elsewhere within a rack that houses the chassis 100. In certain scenarios, such storage resources (e.g., JBOD 155) may be accessed via a SAS expander 150 that is coupled to the backplane 160 of the chassis 100.

In light of the various manners in which storage drives 175a-n, 155 may be coupled to chassis 100, a wide variety of different storage topologies may be supported. Through these supported topologies, storage drives 175a-n, 155 may be logically organized into clusters or other groupings that may be collectively tasked and managed. In some instances, a chassis 100 may include numerous storage drives 175a-n, 155 that are identical, or nearly identical, such as arrays of SSDs of the same manufacturer and model. Accordingly, any firmware updates to storage drives 175a-n, 155 requires the updates to be applied within each of these topologies being supported by the chassis 100. Despite the large number of different storage drive topologies that may be supported by an individual chassis 100, the firmware used by each of these storage devices 175a-n, 155 may be occasionally updated. In some instances, firmware updates may be limited to a single storage drive, but in other instances, firmware updates may be initiated for a large number of storage drives, such as for all SSDs installed in chassis 100.

As illustrated, the chassis 100 of FIG. 1 includes a network controller 140 that provides network access to the sleds 105a-n, 115a-n installed within the chassis. Network controller 140 may include various switches, adapters, controllers, and couplings used to connect chassis 100 to a network, either directly or via additional networking components and connections provided via a rack in which chassis 100 is installed. Network controller 140 operates according to firmware instructions that may be occasionally updated.

Chassis 100 may similarly include a power supply unit 135.

Chassis 100 may also include various I/O controllers 145 that may support various I/O ports that may be used to support various KVM (Keyboard, Video and Mouse) 125a capabilities that provide administrators with the ability to interface with the chassis 100. The chassis management controller 125 may also include a storage module 125c that provides capabilities for managing and configuring certain aspects of the storage devices of chassis 100, such as the storage devices provided within storage sleds 115a-n and within the JBOD 155.

In addition to providing support for KVM 125a capabilities for administering chassis 100, chassis management controller 125 may support various additional functions for sharing the infrastructure resources of chassis 100. In some scenarios, chassis management controller 125 may implement tools for managing the power supply unit 135, network controller 140 and airflow cooling fans 130 that are available via the chassis 100. As described, the airflow cooling fans 130 utilized by chassis 100 may include an airflow cooling system that is provided by a rack in which the chassis 100 may be installed and managed by a cooling module 125b of the chassis management controller 125.

For purposes of this disclosure, an IHS may include any instrumentality or aggregate of instrumentalities operable to compute, calculate, determine, classify, process, transmit, receive, retrieve, originate, switch, store, display, communicate, manifest, detect, record, reproduce, handle, or utilize any form of information, intelligence, or data for business, scientific, control, or other purposes. For example, an IHS may be a personal computer (e.g., desktop or laptop), tablet computer, mobile device (e.g., smart phone), server (e.g., blade server or rack server), a network storage device, or any other suitable device and may vary in size, shape, performance, functionality, and price. An IHS may include Random Access Memory (RAM), one or more processing resources such as a Central Processing Unit (CPU) or hardware or software control logic, Read-Only Memory (ROM), and/or other types of nonvolatile memory. Additional components of an IHS may include one or more disk drives, one or more network ports for communicating with external devices as well as various I/O devices, such as a keyboard, a mouse, touchscreen, and/or a video display. As described, an IHS may also include one or more buses operable to transmit communications between the various hardware components. An example of an IHS is described in more detail below.

FIG. 2 illustrates an example of an IHS 200 configured to implement systems and methods described herein according to one embodiment of the present disclosure. It should be appreciated that although the embodiments described herein may describe an IHS that is a compute sled or similar computing component that may be deployed within the bays of a chassis, a variety of other types of IHSs, such as laptops and portable devices, may also operate according to embodiments described herein. In the illustrative embodiment of FIG. 2, IHS 200 may be a computing component, such as sled 105a-n, 115a-n or other type of server, such as a 1RU server installed within a 2RU chassis or a 1OU form factor chassis, which is configured to share infrastructure resources provided within a chassis 100.

IHS 200 may utilize one or more system processors 205, that may be referred to as CPUs (central processing units). In some embodiments, CPUs 205 may each include a plurality of processing cores that may be separately delegated with computing tasks. Each of the CPUs 205 may be individually designated as a main processor and as a co-processor, where such designations may be based on delegation of specific types of computational tasks to a CPU 205. In some embodiments, CPUs 205 may each include an integrated memory controller that may be implemented directly within the circuitry of each CPU 205. In some embodiments, a memory controller may be a separate integrated circuit that is located on the same die as the CPU 205. Each memory controller may be configured to manage the transfer of data to and from a system memory 210 of the IHS, in some cases using a high-speed memory bus 205a. The system memory 210 is coupled to CPUs 205 via one or more memory buses 205a that provide the CPUs 205 with high-speed memory used in the execution of computer program instructions by the CPUs 205. Accordingly, system memory 210 may include memory components, such as static RAM (SRAM), dynamic RAM (DRAM), NAND Flash memory, suitable for supporting high-speed memory operations by the CPUs 205. In certain embodiments, system memory 210 may combine persistent non-volatile memory and volatile memory.

IHS 200 may utilize a chipset that may be implemented by integrated circuits that are connected to each CPU 205. All or portions of the chipset may be implemented directly within the integrated circuitry of an individual CPU 205. The chipset may provide the CPU 205 with access to a variety of resources accessible via one or more in-band buses. IHS 200 may also include one or more I/O ports 215 that may be used to couple the IHS 200 directly to other IHSs, storage resources, diagnostic tools, and/or other peripheral components. A variety of additional components may be coupled to CPUs 205 via a variety of in-line buses. For instance, CPUs 205 may also be coupled to a power management unit 220 that may interface with a power system of the chassis 100 in which IHS 200 may be installed. In addition, CPUs 205 may collect information from one or more sensors 225 via a management bus.

As illustrated, CPUs 205 may be coupled to a network controller 240, such as provided by a Network Interface Controller (NIC) card that provides IHS 200 with communications via one or more external networks, such as the Internet, a LAN, or a WAN.

As indicated in FIG. 2, in some embodiments, CPUs 205 may be coupled to a PCIe card 255 that includes two PCIe switches 265a-b that operate as I/O controllers for PCIe communications, such as TLPs (Transaction Layer Packets), that are transmitted between the CPUs 205 and PCIe devices and systems coupled to IHS 200.

As indicated in FIG. 2, IHS 200 may support storage drives 235a-b in various topologies, in the same manner as described with regard to the chassis 100 of FIG. 1. In the illustrated embodiment, storage drives 235a are accessed via a hardware accelerator 250, while storage drives 235b are accessed directly via PCIe switch 265b. In some embodiments, the storage drives 235a-b of IHS 200 may include a combination of both SSD and magnetic disk storage drives. In other embodiments, all of the storage drives 235a-b of IHS 200 may be identical, or nearly identical. In all embodiments, storage drives 235a-b operate according to firmware instructions that may be occasionally updated.

As illustrated, PCIe switch 265a is coupled via a PCIe link to a hardware accelerator 250 that may be connected to the IHS via a removable card or baseboard that couples to a PCIe connector of the IHS 200. In some embodiments, hardware accelerator 250 includes a programmable processor that can be configured for offloading functions from CPUs 205.

As illustrated in FIG. 2, PCIe switches 265a-b may also support PCIe couplings with one or more GPUs (Graphics Processing Units) 260. Embodiments may include one or more GPU cards, where each GPU card is coupled to one or more of the PCIe switches 265a-b, and where each GPU card may include one or more GPUs 260. In some embodiments, PCIe switches 265a-b may transfer instructions and data for generating video images by the GPUs 260 to and from CPUs 205. Accordingly, GPUs 260 may include one or more hardware-accelerated processing cores that are optimized for performing streaming calculation of vector data, matrix data and/or other graphics data, thus supporting the rendering of graphics for display on devices coupled either directly or indirectly to IHS 200. In some instances, GPUs may be utilized as programmable computing resources for offloading other functions from CPUs 205, in the same manner as hardware accelerator 250. GPUs 260 may operate according to firmware instructions that may be occasionally updated.

As illustrated in FIG. 2, PCIe switches 265a-b may support PCIe connections in addition to those utilized by GPUs 260 and hardware accelerator 250, where these connections may include PCIe links of one or more lanes. For instance, PCIe connectors 245 supported by a printed circuit board of IHS 200 may allow various other systems and devices to be coupled to IHS. Through PCIe connectors 245, a variety of data storage devices, graphics processors and network interface cards may be coupled to IHS 200, thus supporting a wide variety of topologies of devices that may be coupled to the IHS 200.

As described, IHS 200 includes a remote access controller 230 that supports remote management of IHS 200 and of various internal components of IHS 200. In certain embodiments, remote access controller 230 may operate from a different power plane from the CPUs 205 and other components of IHS 200, thus allowing the remote access controller 230 to operate, and manage tasks to proceed, while the processing cores of IHS 200 are powered off. Various functions provided by the BIOS, including launching the operating system of the IHS 200, and/or functions of a TPM may be implemented or supplemented by the remote access controller 230. In some embodiments, the remote access controller 230 may perform various functions to verify the integrity of the IHS 200 and its hardware components prior to initialization of the operating system of IHS 200 (i.e., in a bare-metal state). In some embodiments, certain operations of the remote access controller 230, such as the operations described herein for updating firmware used by managed hardware components of IHS 200, may operate using validated instructions, and thus within the root of trust of IHS 200.

In some embodiments, remote access controller 230 may include a service processor 230a, or specialized microcontroller, which operates management software that supports remote monitoring and administration of IHS 200. The management operations supported by remote access controller 230 may be remotely initiated, updated, and monitored via a remote management interface 101, such as described with regard to FIG. 1. Remote access controller 230 may be installed on the motherboard of IHS 200 or may be coupled to IHS 200 via an expansion slot or other connector provided by the motherboard. In some instances, the management functions of the remote access controller 230 may utilize information collected by various managed sensors 225 located within the IHS. For instance, temperature data collected by sensors 225 may be utilized by the remote access controller 230 in support of closed-loop airflow cooling of the IHS 200. As indicated, remote access controller 230 may include a secured memory 230e for exclusive use by the remote access controller in support of management operations.

In some embodiments, remote access controller 230 may implement monitoring and management operations using MCTP (Management Component Transport Protocol) messages that may be communicated to managed devices 205, 235a-b, 240, 250, 255, 260 via management connections supported by a sideband bus 253. In some embodiments, the remote access controller 230 may additionally or alternatively use MCTP messaging to transmit Vendor Defined Messages (VDMs) via the in-line PCIe switch fabric supported by PCIe switches 265a-b. In some instances, the sideband management connections supported by remote access controller 230 may include PLDM (Platform Level Data Model) management communications with the managed devices 205, 235a-b, 240, 250, 255, 260 of IHS 200.

As illustrated, remote access controller 230 may include a network adapter 230c that provides the remote access controller with network access that is separate from the network controller 240 utilized by other hardware components of the IHS 200. Through secure connections supported by network adapter 230c, remote access controller 230 communicates management information with remote management interface 101. In support of remote monitoring functions, network adapter 230c may support connections between remote access controller 230 and external management tools using wired and/or wireless network connections that operate using a variety of network technologies. As a non-limiting example of a remote access controller, the integrated Dell Remote Access Controller (iDRAC) from Dell® is embedded within Dell servers and provides functionality that helps information technology (IT) administrators deploy, update, monitor, and maintain servers remotely.

Remote access controller 230 supports monitoring and administration of the managed devices of an IHS via a sideband bus 253. For instance, messages utilized in device and/or system management may be transmitted using I2C sideband bus 253 connections that may be individually established with each of the respective managed devices 205, 235a-b, 240, 250, 255, 260 of the IHS 200 through the operation of an I2C multiplexer 230d of the remote access controller.

In certain embodiments, the service processor 230a of remote access controller 230 may rely on an I2C co-processor 230b to implement sideband I2C communications between the remote access controller 230 and the managed hardware components 205, 235a-b, 240, 250, 255, 260 of the IHS 200. The I2C co-processor 230b may be a specialized co-processor or micro-controller that is configured to implement an I2C bus interface used to support communications with managed hardware components 205, 235a-b, 240, 250, 255, 260 of IHS. In some embodiments, the I2C co-processor 230b may be an integrated circuit on the same die as the service processor 230a, such as a peripheral system-on-chip feature that may be provided by the service processor 230a. The I2C sideband bus 253 is illustrated as single line in FIG. 2. However, sideband bus 253 may be comprised of multiple signaling pathways, where each may be comprised of a clock line and data line that couple the remote access controller 230 to I2C endpoints 205, 235a-b, 240, 250, 255, 260.

In various embodiments, an IHS 200 does not include each of the components shown in FIG. 2. In various embodiments, an IHS 200 may include various additional components in addition to those that are shown in FIG. 2. Furthermore, some components that are represented as separate components in FIG. 2 may in certain embodiments instead be integrated with other components. For example, in certain embodiments, all or a portion of the functionality provided by the illustrated components may instead be provided by components integrated into the one or more processor(s) 205 as a systems-on-a-chip.

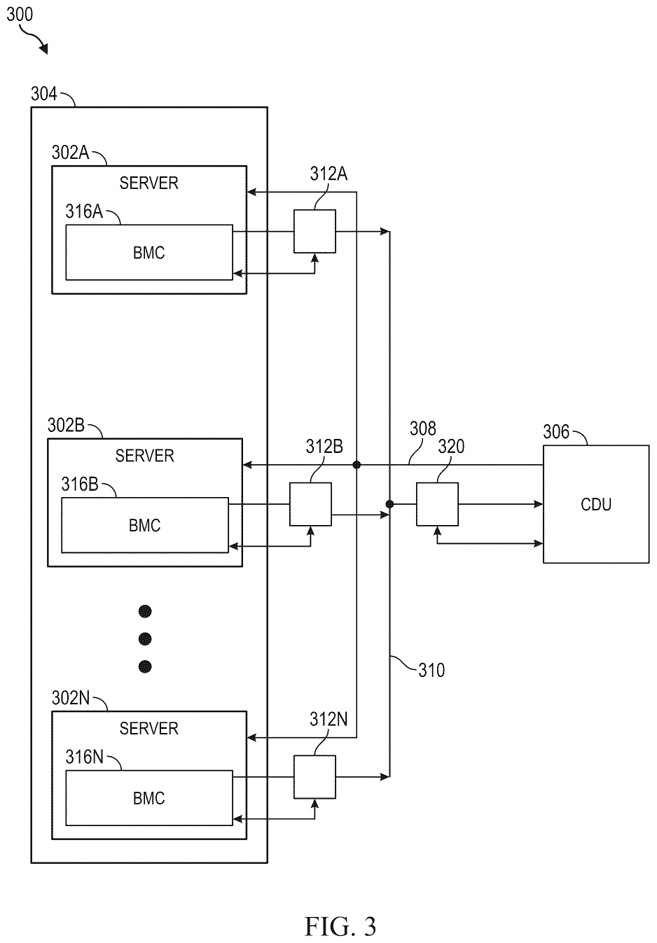

FIG. 3 illustrates an example ultrasonic communication system 300 that may be used to provide communication from a CDU to the servers of a data center according to one embodiment of the present disclosure. The ultrasonic communication system 300 includes multiple servers 302a-n (collectively 302) configured in a computing rack 304 or other type of computing cluster that are cooled by a CDU 306. The CDU 306 is coupled to each server 302 via input lines 308 that provide chilled cooling fluid to each server 302 and return lines 310 that return the warmed fluid back to the CDU 306. According to embodiments of the present disclosure, each server 302 is coupled to a transducer assembly 312a-n (collectively 312) that converts ultrasonic pressure waves in the lines 308, 310 to and from electrical signals that are provided to BMCs 316a-n (collectively 316) configured in each server 302. Additionally, the CDU 306 includes a transducer assembly 320 that converts ultrasonic pressure waves in the lines 308, 310 to electrical signals that are provided to the CDU 306. As will be described in detail herein below, these ultrasonic pressure waves may be used to provide communication between the CDU 306 and the servers 302 in the computing rack 304. The ultrasonic transducer 312 and ultrasonic transducer 320 may be coupled to either of the input line 308 or return line 310.

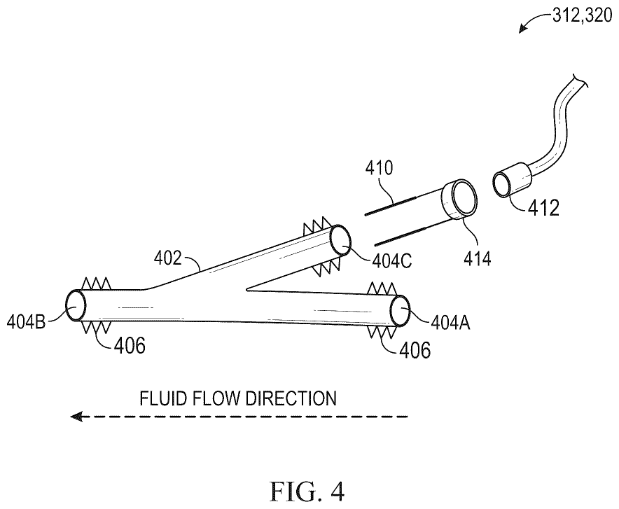

FIG. 4 illustrates an exploded view showing several components of the example transducer 312, 320 that may be used for converting ultrasonic pressure waves in the lines 308, 310 to electrical signals and/or converting electrical signals to ultrasonic pressure waves according to one embodiment of the present disclosure. The ultrasonic transducer 312 includes a Y-shaped coupling 402 with a first, second, and third ends 404a-c (collectively 404). Each end 404 has a barb 406. For example, barbs 406 configured on the first end 404a and second end 404b may be used for being coupled within either of the input line 308 or return line 310 of the CDU 306. Although the ultrasonic transducer 312, 320 is shown to have a fluid flow in the direction from end 404a to 404b, it should be appreciated that the ultrasonic transducer 312, 320 may also be implemented with a fluid flow in the direction from end 404b to 404a.

The ultrasonic transducer 312 also includes an acoustic coupler 410 that is configured for placement on the third end 404c of the Y-shaped coupling 402, and couples an ultrasonic transducer 412 to the third end 404c of the Y-shaped coupling 402. Thus, the ultrasonic transducer 412 is in fluid communication with the fluid in either of the input line 308 or return line 310 of the CDU 306, and thus transmit or receive signals from another ultrasonic transducer 412 configured in another ultrasonic transducer 312 in the system. In one embodiment, the acoustic coupler 410 may include an impedance matching layer 414 that matches the impedance of the ultrasonic transducer 412 to the working fluid in the input line 308 or return line 310 of the CDU 306. Additionally, the impedance matching layer 414 may fit over the third end 404c to seal the working fluid within the Y-shaped coupling 402.

The ultrasonic transducer 412 essentially changes electrical signals into pressure waves, and may be, for example, a piezo-electric transducer that is a narrowband resonant device (e.g., +1-2 kHz), and typically tuned to 40 to 50 kHz (e.g., 45 kHz). In such a case, the piezo-electric transducer may have a cutoff frequency f=c/(1.71'd), where c is the speed of sound in a medium (e.g., working fluid), d is tube Inner Diameter (ID). Under this cutoff frequency, a near Total Internal Reflection may be achieved. That is, the signal may stay in the working fluid and does not easily refract into the ambient environment.

In one embodiment, the Y-shaped coupling 402 may have an inner diameter that is selected to optimize the acoustic gain. For an example in which the ultrasonic transducer 412 operates at 45 kHz, the Y-shaped coupling 402 may be configured to have an inner diameter of 8.3 millimeters (e.g., λ/4) or 16.6 millimeters (e.g., λ/2) to optimize the acoustic gain. In another embodiment, the third end 404c may form an angle with the first end 404a that is relatively small to minimize reflections that may occur at the juncture of the third end 404c and the first end 404a. For example, the Y-shaped coupling 402 may be configured to have an angle of the third end 404c relative to the first end 404a that is within the range of 5-15 degrees.

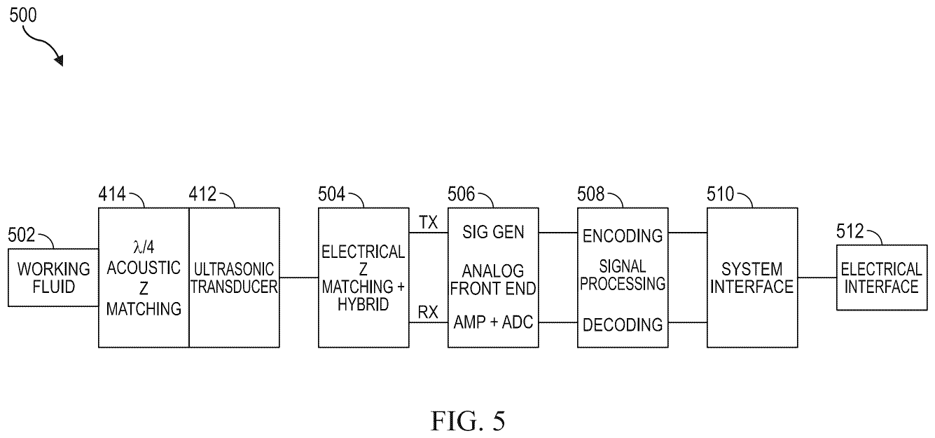

FIG. 5 illustrates an example block diagram 500 showing how the ultrasonic transducer 312 may be used to convert ultrasonic signals to and from electrical signals according to one embodiment of the present disclosure. The block diagram includes an impedance matching layer 414 that acoustically couples the working fluid 502 to the ultrasonic transducer 412. The block diagram 500 also includes an electrical impedance match, and hybrid device 504 to separate the transmitted signals from the received signals, an analog front end 506 that functions as a burst generator for transmitting, amplifier and a filter and an Analog to Digital Converter (ADC) for receiving, a signal processing block 508 that includes a Digital Signal Processor (DSP) that performs data formatting & encoding for transmitting, and matched filtering plus data decoding for receiving, a system interface 510 that provides interface host MCU and data buffering for transmitted and received signals, and an electrical interface 512 (e.g., USB connector) for coupling the ultrasonic transducer 312 to a management device, such as BMC 316.

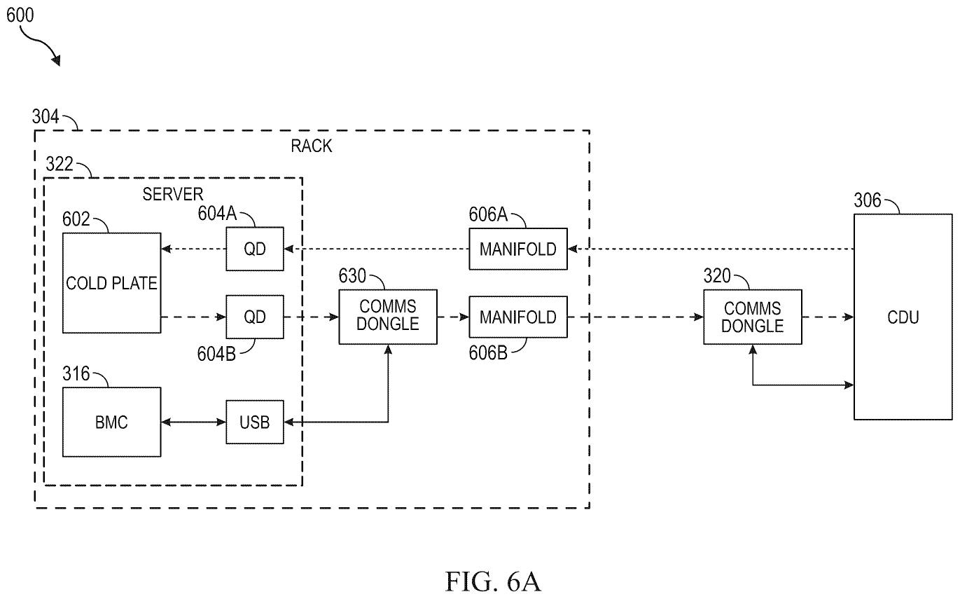

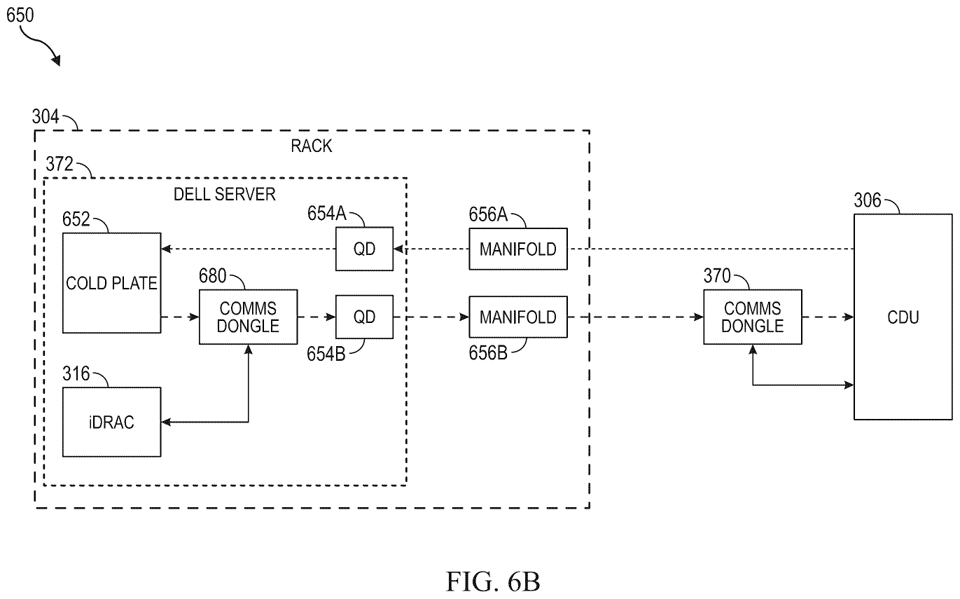

FIGS. 6A and 6B illustrate several embodiments of example transducer assembly configurations 600, 650 that may be used by the ultrasonic communication system 300 according to one embodiment of the present disclosure. In particular, the transducer assembly configuration 600 may be used in cases where the server 322 is an existing server or one provided by a third party server vendor, while the transducer assembly configuration 650 may be used in cases where the server 372 is newly designed to be used with the ultrasonic communication system 300.

In particular, the transducer assembly configuration 600 includes a server 322 configured with a cold plate 602 in fluid communication with a CDU 306 through a pair of Quick Disconnects (Qds) 604a-b, and a pair of manifolds 606a-b. In this particular case, the transducer assembly 630 is configured external to the server 322 it is designed to work with. The transducer assembly configuration 650, on the other hand, includes a server 372 is configured with a cold plate 652 in fluid communication with a CDU 306 through a pair of Quick Disconnects (Qds) 654a-b, and a pair of manifolds 656a-b. In this case, the transducer assembly 680 is configured internally within the server 372 it is designed to work with. Whereas the transducer assembly configuration 600 may provide basic communication messages, such as receiving telemetry information from the CDU 306, or transmitting emergency conditions (e.g., a detected leak), the transducer assembly configuration 650 may provide more advanced features, such as receiving telemetry information from the CDU 306 or from other servers 372, or transmitting emergency conditions as well as performing a shutdown, and/or cluster job migration behaviors.

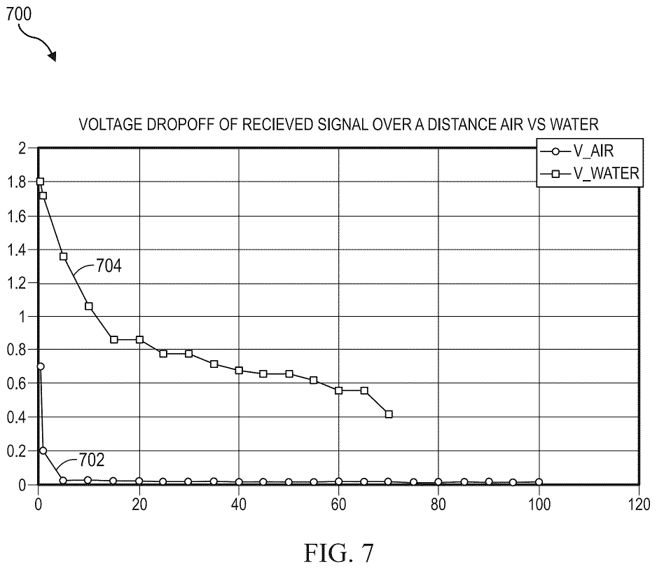

FIG. 7 illustrates an example graph 700 showing how the ultrasonic communication system 300 may perform according to one embodiment of the present disclosure. In particular, the graph 700 shows a received signal strength plot 702 over distance that may be experienced by a pair of ultrasonic transducers when they communicate via an air medium, while a received signal strength plot 704 over distance that may be experienced by a pair of ultrasonic transducers when they communicate via a water medium. The Y-axis represents a voltage drop off, which the X-axis represents a distance between the pair of ultrasonic transducers in cent-meters (cm). As shown, the air voltage drop off plot 702 drops off to near zero when the pair of ultrasonic transducers are separated by only 5 cm, while the water voltage drop off plot 704 shows that they can still communicate when separated by up to 70 cm.

The ultrasonic transducer 312, in general, is a resonant device that is tuned to an approximate 40 kHz center frequency. It can operate +/−2 kHz away from center with attenuated response. To carry data, it should be modulated. Amplitude Modulation (AM) and Frequency Modulation (FM) is possible. For best decoding characteristics in the presence of noise, a sinusoidal chirp 802 is desired that is shaped by a smooth window, which has good auto-correlation properties. A second layer of modulation may be added to further improve noise immunity. Advantage of the narrow bandwidth of the transceiver may be taken to minimize signal generation effort. A square wave burst is easy to generate on digital I/O pins and square turns into sine on transceiver due to narrow bandwidth that inherently filters out harmonics. Swept frequency signal amplitude is shaped by transceiver frequency response, automatically creating the ideal window, with no need to use high speed Digital to Analog Converters (DACs).

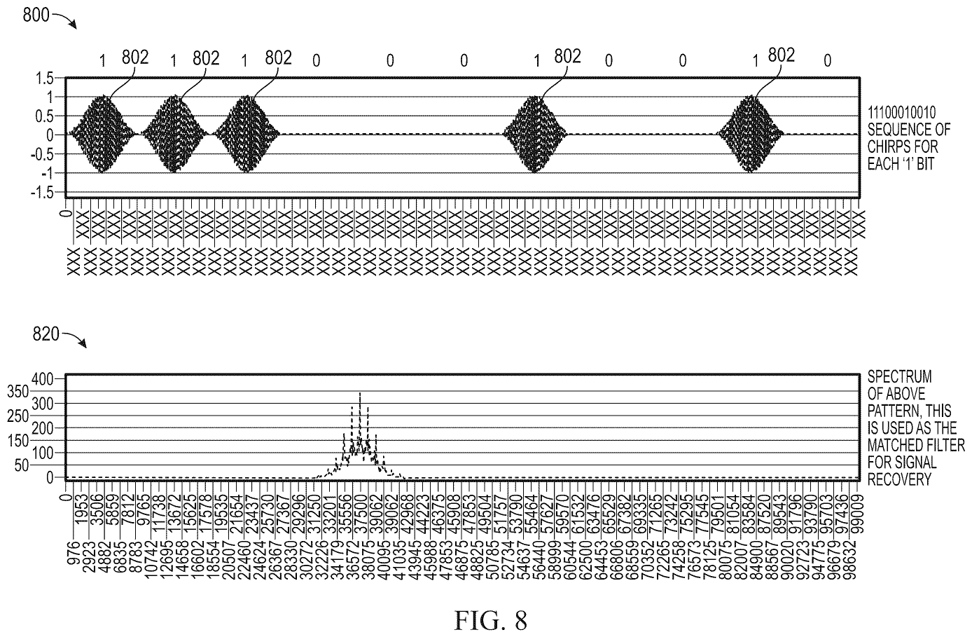

FIG. 8 illustrates a graph 800 showing an example pseudo-random binary sequence (PRBS) that may be used to enhance noise immunity of the ultrasonic communication system 300 according to one embodiment of the present disclosure. In particular, graph 800 shows a “11100010010” sequence of chirps that may be used to represent a logic “1” bit, while graph 820 shows a frequency spectrum of graph 800, which can be used as a matched filter for signal recovery. For noise immunity, a layer of encoding may be added by using multiple chirps per bit. The pattern of the chirps is selected to have good auto correlation characteristics. Several different types of pseudo-random binary sequences (PRBS) may be suitable. In the present example, a 11100010010 sequence is used. For full duplex operation, each node may have a unique PRBS code. Conventionally, Direct Sequence Spread Spectrum (DSSS) uses multiple chips per bit to up-spread and increase bandwidth in which all bits regardless of value are XORed with the multi-bit spreading code to increase toggle rate. The present embodiment, on the other hand, is down-spreading the bits. Stretch the bit time to fit multiple chirps that follow the selected pseudo-random pattern. Only the ‘1’ bits are encoded, nothing is transmitted during ‘0’ bits. In this manner, the net bit rate is lower, but noise immunity is improved. Although only chirps 802 are shown for ‘1’ bits, it should be appreciated that other types of chirps may also be used for ‘0’ bits without departing from the spirit and scope of the present disclosure.

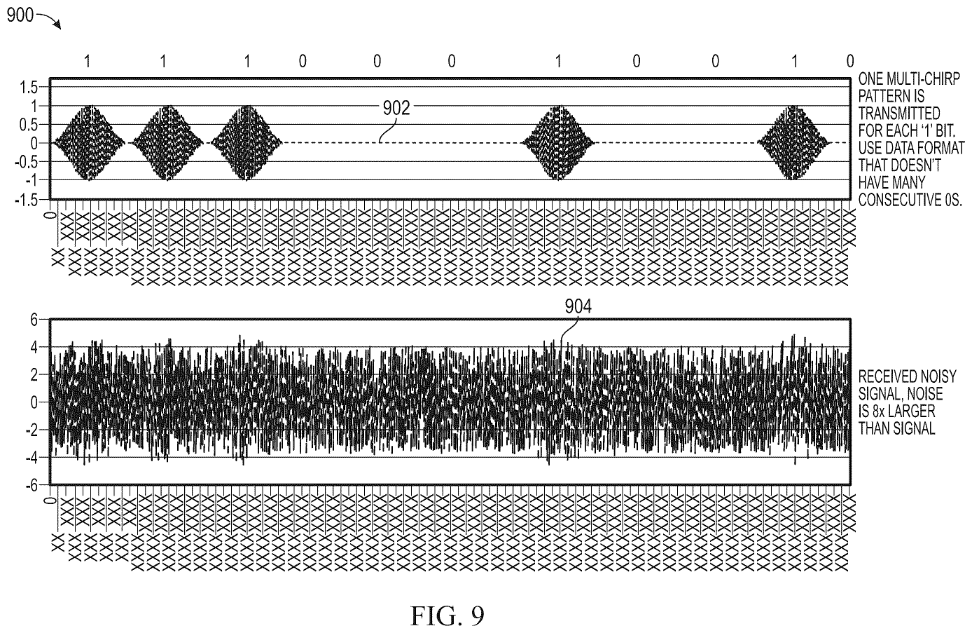

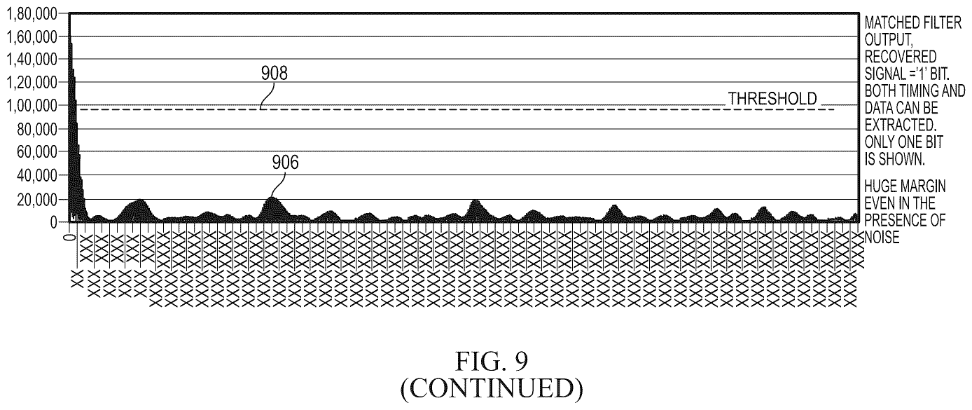

FIG. 9 illustrates an example graph 900 showing how a signal may be recovered in the presence of noise according to one embodiment of the present disclosure. In particular, graph 900 includes a PRBS plot 902 that is transmitted through either of the input line 308 or return line 310, a noise plot 904 showing a measured level of noise present in the input line 308 or return line 310, and a matched filter output 906 showing how a signal may be recovered that is above a threshold value 908 for reliably recovering the signal from the noise. In one embodiment, one multi-chirp PRBS pattern is transmitted for each ‘1’ bit. In another embodiment, a data format may be used that does not have many consecutive ‘0’s. As shown although the noise is larger than the received noisy signal, the matched filter output is able to successfully recover the signal, which in this particular instance, is a single bit. In another embodiment, the DSP that processes the received signals can stretch or compress the received signal in the time domain to zero out the doppler shift due to fluid flow. This could be pre-wired knowing the fluid flow velocity and direction, or adaptively, (e.g., automatically adjust the sampling rate in a closed loop to maximize the correlator output). Such a feature may be useful for cases long PN.

Although the invention(s) is/are described herein with reference to specific embodiments, various modifications and changes can be made without departing from the scope of the present invention(s), as set forth in the claims below. Accordingly, the specification and figures are to be regarded in an illustrative rather than a restrictive sense, and all such modifications are intended to be included within the scope of the present invention(s). Any benefits, advantages, or solutions to problems that are described herein with regard to specific embodiments are not intended to be construed as a critical, required, or essential feature or element of any or all the claims.

Unless stated otherwise, terms such as “first” and “second” are used to arbitrarily distinguish between the elements such terms describe. Thus, these terms are not necessarily intended to indicate temporal or other prioritization of such elements. The terms “coupled” or “operably coupled” are defined as connected, although not necessarily directly, and not necessarily mechanically. The terms “a” and “an” are defined as one or more unless stated otherwise. The terms “comprise” (and any form of comprise, such as “comprises” and “comprising”), “have” (and any form of have, such as “has” and “having”), “include” (and any form of include, such as “includes” and “including”) and “contain” (and any form of contain, such as “contains” and “containing”) are open-ended linking verbs. As a result, a system, device, or apparatus that “comprises,” “has,” “includes” or “contains” one or more elements possesses those one or more elements but is not limited to possessing only those one or more elements. Similarly, a method or process that “comprises,” “has,” “includes” or “contains” one or more operations possesses those one or more operations but is not limited to possessing only those one or more operations.

What is claimed is:

1. An ultrasonic communication system comprising:
a plurality of servers configured in a computing cluster, each server in fluid communication with a Cooling Distribution Unit (CDU) via an input line and a return line;
a plurality of first ultrasonic transducers configured in at least one of a first of the input line or the return line proximate the servers or the CDU; and
a second ultrasonic transducer configured in at least one of a second of the input line or the return line proximate at least a second one of one of the servers or the CDU, wherein the first of at least one of the server or the CDU is configured to communicate with the second of the at least one of the servers or the CDU using the second ultrasonic transducer and the first ultrasonic transducer.

2. The ultrasonic communication system of claim 1, wherein the ultrasonic transducer comprises a piezo-electric transducer.

3. The ultrasonic communication system of claim 1, wherein the inner diameter is selected to form a harmonic in the cooling fluid with the frequency of the transducer.

4. The ultrasonic communication system of claim 1, further comprising an impedance matching layer configured to match the impedance of a cooling fluid with the eat.

5. The ultrasonic communication system of claim 1, wherein the ultrasonic transducer comprises a Y-shaped coupling.

6. The ultrasonic communication system of claim 5, wherein a third end of the Y-shaped coupling forms an angle with a first end of the Y-shaped coupling that is relatively small to minimize reflections that may occur at the juncture of the third end and the first end.

7. The ultrasonic communication system of claim 1, wherein the first ultrasonic transducer is configured inside of its respective server.

8. The ultrasonic communication system of claim 1, wherein the first ultrasonic transducer is configured outside of its respective server.

9. The ultrasonic communication system of claim 1, wherein the first ultrasonic transducer is in communication with a Baseboard Management Controller (BMC) inside of its respective server.

10. The ultrasonic communication system of claim 1, wherein the first ultrasonic transducers are configured to communicate with the second ultrasonic transducer using spread-spectrum encoding.

11. An Information Handling System (IHS) comprising:
a plurality of servers configured in a computing cluster, each server in fluid communication with a Cooling Distribution Unit (CDU) via an input line and a return line;
a plurality of first ultrasonic transducers configured in at least one a first of the input line or the return line proximate the servers or the CDU; and
a second ultrasonic transducer configured in at least one of a second of the input line or the return line proximate a second server or the CDU, wherein the first server or CDU is configured to communicate with the second of the servers or the CDU using the second ultrasonic transducer and the first ultrasonic transducer.

12. The IHS of claim 11, wherein the ultrasonic transducer comprises a piezo-electric transducer.

13. The IHS of claim 11, wherein the inner diameter is selected to form a harmonic in the cooling fluid with the frequency of the transducer.

14. The IHS of claim 11, further comprising an impedance matching layer configured to match the impedance of a cooling fluid with the eat.

15. The IHS of claim 11, wherein the ultrasonic transducer comprises a Y-shaped coupling.

16. The IHS of claim 15, wherein a third end of the Y-shaped coupling forms an angle with a first end of the Y-shaped coupling that is relatively small to minimize reflections that may occur at the juncture of the third end and the first end.

17. The IHS of claim 11, wherein the first ultrasonic transducer is configured inside of its respective server.

18. The IHS of claim 11, wherein the first ultrasonic transducer is configured outside of its respective server.

19. The IHS of claim 11, wherein the first ultrasonic transducer is in communication with a Baseboard Management Controller (BMC) inside of its respective server.

20. The IHS of claim 11, wherein the first ultrasonic transducers are configured to communicate with the second ultrasonic transducer using spread-spectrum encoding.
